(19) United States
(12) Patent Application Publication
(10) Pub. No.: US 2022/0044100 A1
(43) Pub. Date: Feb. 10, 2022

(54) PARALLEL ARCHITECTURES FOR NANOPHOTONIC COMPUTING

(71) Applicant: The Regents of the University of California, Oakland, CA (US)

(72) Inventor: Sung-Joo Ben Yoo, Davis, CA (US)

(73) Assignee: The Regents of the University of California, Oakland, CA (US)

(21) Appl. No.: 16/945,285

(22) Filed: Jul. 31, 2020

Related U.S. Application Data
(60) Provisional application No. 62/881,241, filed on Jul. 31, 2019.
(60) Provisional application No. 62/891,986, filed on Aug. 27, 2019.

(51) Int. Cl. G06N 3/063; G06N 3/04; G02F 1/295

(52) U.S. Cl. CPC G06N 3/063; G02F 1/2955; G06N 3/04

(57) ABSTRACT

The disclosed embodiments relate to a nanophotonic computing system, which comprises a set of nanophotonic computing elements and an optical interconnect that interconnects the set of nanophotonic computing elements. The optical interconnect includes one or more nanophotonic synaptic interconnect devices (NSIDs), which provide unitary and all-to-all interconnects between NSID inputs and NSID outputs, wherein each NSID comprises free-space propagation regions connected by an array of waveguides to facilitate routing different wavelengths. These waveguides include phase modulators for varying optical lengths of the waveguides, wherein varying the optical lengths of the waveguides facilitates adjusting weights on interconnections through the NSID in a lossless manner.

### CROSS-REFERENCE TO RELATED APPLICATIONS

This application claims priority under 35 U.S.C. § 119(e) to U.S. Provisional Application Ser. No. 62/891,986, entitled “Nanophotonic Parallel Processors,” by inventor Sung-Joo Ben Yoo, filed on 27 Aug. 2019 (Attorney Docket No. UC19-093-1PSP). This application also claims priority under 35 U.S.C. § 119(e) to U.S. Provisional Application Ser. No. 62/881,241, entitled “Multi-Wavelength Nanophotonic Neural Computing,” by inventor Sung-Joo Ben Yoo, filed on 31 Jul. 2019 (Attorney Docket No. UC19-788-1PSP). The contents of the above-listed applications are hereby incorporated by reference herein.

### GOVERNMENT LICENSE RIGHTS

This invention was made with U.S. government support under grant number FA9550-18-1-0186 awarded by the Air Force Office of Scientific Research (AFOSR). The U.S. government has certain rights in the invention.

### BACKGROUND

### Field

The disclosed embodiments generally relate to designs for photonic computing systems. More specifically, the disclosed embodiments relate to new parallel architectures for nanophotonic computing systems, which can be implemented using multi-stage nanophotonic circuits or multi-wavelength interconnections between nanophotonic neural circuits.

### Related Art

As computer systems become increasingly faster, communication delays are beginning to significantly constrain computational performance. Most modern computer systems are based on a “von Neumann architecture,” wherein data is retrieved from memory and is processed at a central processing unit (CPU). Unfortunately, as computer systems become faster, the limited data throughput that is available between CPU and memory (and between levels of cache within the CPU) is beginning to significantly limit computational performance and associated energy efficiency. This throughput-related performance limitation between CPU and memory is referred to as the “von Neumann bottleneck.”

To overcome the performance problems associated with the von Neumann bottleneck, a significant amount of research has been directed toward computing systems that use “photonic circuits” to facilitate various parallel processing operations. Some researchers have investigated using lenses to perform optical computations, which can potentially provide a high degree of parallelism. (For example, see Demetri Psaltis, David Casasent, Deborah Neft, Mark Carlotto, “Accurate Numerical Computation By Optical Convolution,” Proc. SPIE 0232, 1980 Intl Optical Computing Conf II, 22 Aug. 1980; https://doi.org/10.1117/12.958883, 1980, p. 6.) Unfortunately, it has proven impractical to perform computations in this way because of the limited scalability of such bulky optical components when considering large scale computing systems.

Other researchers have investigated using “photonic neuromorphic circuits,” which attempt to mimic the behavior of neural networks in the human brain. Neuromorphic circuits comprise a collection of elements that model individual neurons with synaptic interconnects, wherein each neuron receives input pulses from upstream neurons through synaptic interconnects (upstream) and generates output pulses that are directed to downstream neurons via synaptic interconnects (downstream). The large number of interconnections among individual neurons in a neuromorphic circuit makes it possible to achieve massively parallel computing and to overcome the limitations coming from the von Neumann bottleneck in conventional computing systems (also called “von Neumann computing systems”). These neuromorphic circuits provide energy efficiency and throughput improvements for certain types of computation tasks, such as pattern-recognition operations in relatively small-scale electronic neuromorphic computing systems as compared with electronic von Neumann computing systems. (Please see M. Davies, N. Srinivasa, T. Lin, G. Chinya, Y. Cao, S. Choday, G. Dimou, P. Joshi, N. Imam, S. Jain, Y. Liao, C. Lin, A. Lines, R. Liu, D. Mathaikutty, S. McCoy, A. Paul, J. Tse, G. Venkataramanan, Y. Weng, A. Wild, Y. Yang, and H. Wang, “Loihi: A Neuromorphic Manycore Processor with On-Chip Learning,” IEEE Micro, vol. 38, no. 01, pp. 82-99, 2018, doi: 10.1109/MM.2018.112130359. Also see P. A. Merolla, J. V Arthur, R. Alvarez-Icaza, A. S. Cassidy, J. Sawada, F. Akopyan, B. L. Jackson, N. Imam, C. Guo, Y. Nakamura, B. Brezzo, I. Vo, S. K. Esser, R. Appuswamy, B. Taba, A. Amir, M. D. Flickner, W. P. Risk, R. Manohar, and D. S. Modha, “A million spiking-neuron integrated circuit with a scalable communication network and interface,” Science (80-.)., vol. 345, no. 6197, pp. 668 LP-673, August 2014, doi: 10.1 126/science.1254642. Also see R. Carney, K. Bouchard, P. Calafiura, D. Clark, D. Donofrio, M. Garcia-Sciveres, and J. Livezey, “Neuromorphic Kalman filter implementation in IBM's TrueNorth,” 2017, doi: 10.1088/1742-6596/898/4/042021.)

It is widely anticipated that optical neuromorphic computing can bring far more advantages in energy-efficiency, throughput, and scalability compared with the electronic counterparts. However, it has proven to be quite challenging in practice to provide the required “synaptic weights” for the photonic interconnections between individual photonic neurons to effectively perform neuromorphic computations.

Hence, what is needed are new photonic neuromorphic computing systems that support a high degree of parallelism and a large set of synaptic weights, without the aforementioned shortcomings of existing electronic systems.

### SUMMARY

The disclosed embodiments relate to a nanophotonic computing system, which comprises a set of nanophotonic computing elements and an optical interconnect that interconnects the set of nanophotonic computing elements. More specifically, it is a photonic neuromorphic computing system comprising a large number of nanophotonic neurons that interconnect with many other nanophotonic neurons via photonic synaptic interconnects.

The photonic synaptic interconnects includes one or more photonic components comprising multiple waveguides. One particular example is arrayed-waveguide grating routers (AWGRs), which provide cyclic, single-wavelength, all-to-all routing between AWGR inputs and AWGR outputs, wherein each AWGR comprises free-propagation-region slabs connected by an array of waveguides to facilitate routing different wavelengths. In the cyclic AWGRs, the length of the arrayed waveguides increments linearly so that the optical phase increments linearly with the arrayed waveguides for the output waveguides of the AWGRs, which will receive signals of differing wavelengths to be routed. Hence, in this particular embodiment of the cyclic AWGR, they synaptic weight values are ‘1’ for the wavelengths routed and ‘0’ for the other wavelengths.

The inventive nanophotonic synaptic interconnects can achieve arbitrary values of synaptic weights for each input neuron-output neuron pair at each wavelength by adjusting optical path lengths or optical phase delays for each wavelength at these array waveguides. Hence, these waveguides include phase modulators for varying optical lengths of the waveguides, wherein varying the optical lengths of the waveguides facilitates adjusting weights on interconnections through the nanophotonic synaptic interconnects in a lossless manner. Lossless interconnects are represented by unitary matrices. Hence, the inventive nanophotonic synaptic interconnect device is a device that represents a unitary matrix at each wavelength. In some configurations, this inventive nanophotonic synaptic interconnect device (NSID) can represent an arbitrary unitary matrix at each wavelength independently of each other.

As previously stated, the neuromorphic computing system comprises many neurons interconnecting with many other neurons via the synaptic interconnects. In some embodiments, the set of nanophotonic computing elements comprises a set of spiking nanophotonic neurons, wherein each spiking nanophotonic neuron operates by integrating weighted outputs received from other spiking nanophotonic neurons, and producing a threshold-based nonlinear response that generates output pulses, which are broadcast to other spiking nanophotonic neurons.

In some embodiments, the set of spiking nanophotonic neurons is interconnected through the photonic synaptic interconnects to form a recurrent photonic neural network. The synaptic weights in this recurrent neural network can be adjusted by using the phase modulators in the array arms of the photonic synaptic interconnects to adjust corresponding synaptic weights in the photonic synaptic interconnect device.

In some embodiments, the synaptic weights can be positive weights or negative weights to represent positive or negative electrical field superpositions. More generally, the synaptic weight values are represented in phase and amplitude values.

In some embodiments, the nanophotonic computing system is organized as a set of interconnected neuron clusters, wherein each neuron cluster comprises: an array of spiking nanophotonic neurons; an input synaptic coupler comprising an input NSID connecting inputs of the neuron cluster to inputs of the array of spiking nanophotonic neurons; and an output synaptic coupler comprising an output NSID connecting outputs of the array of spiking nanophotonic neurons to outputs of the neuron cluster.

In some embodiments, the set of detectors is implemented within a field-programmable gate array (FPGA).

In some embodiments, the reconfigurable couplers comprise 2×2 Nano-Electro-Mechanical System (NEMS)-Mach-Zehnder interferometer (MZI) synapses to achieve optical reconfiguration with nearly zero static energy consumption.

In some embodiments, the NEMS-MZI synapses include tunable NEMS phase shifters.

In some embodiments, the reconfigurable couplers comprise 2×2 synapses composed of a phase-change material embedded in an MZI.

In some embodiments, the phase-change material comprises GeSbTe (GST) or Ge₂Sb₂Se₄Te₁(GSST).

In some embodiments, the phase modulators in the NSID comprise thermo-optic phase modulators or electro-optic phase modulators.

In some embodiments, the phase modulators in the NSID comprise resonant rings that are over-coupled to corresponding waveguides in the NSID so that optical loss is nearly negligible regardless of wavelength, wherein the resonant rings can be thermally or electro-optically tuned to have resonant wavelengths on the blue or red side of a corresponding laser wavelength so that the optical phase can be modulated from zero to 2π.

In some embodiments, each nanophotonic neuron comprises: an excitatory-input photo detector that converts an optical excitatory input signal into a corresponding electrical excitatory input signal; an inhibitory-input photo detector that converts an optical inhibitory input signal into a corresponding electrical inhibitory input signal; an electrical neuron that receives the electrical excitatory and inhibitory input signals, and generates an electrical output signal, which includes periodic voltage spikes that are triggered by integration of the electrical excitatory and inhibitory input signals; and a light-emitting output device, which converts the electrical output signal into a corresponding optical output signal.

In some embodiments, each electrical neuron in a nanophotonic neuron implements an integrate-and-fire model, wherein the electrical excitatory and inhibitory input signals are integrated until a firing threshold is reached, which causes the electrical neuron to fire and generate a voltage spike on the electrical output signal.

In another embodiment, the nanophotonic computing system can utilize metaphotonics with optical waves propagating in free space instead of waveguides. Such a nanophotonic computing system comprises: an optical source; a stack of photonic layers composed of metalenses and intervening specialized modulators, wherein each metalens comprises a flat lens metastructure composed of subwavelength scale elements, and wherein each specialized modulator comprises a modulator metastructure composed of subwavelength scale elements; and an optical detector array. During operation, this nanophotonic computing system is configured to channel light emanating from the optical source through the stack of photonic layers and onto the optical detector array to facilitate optical computing operations

In some embodiments, each specialized modulator comprises a liquid-crystal-on-silicon-based spatial light modulator.

In some embodiments, the metalenses perform wavelength-dependent diffraction, focusing and collimating operations.

In some embodiments, the system includes an optical or electrical feedback path that facilitates cycling through the stack of photonic layers to perform multi-layer optical processing operations, as performed in multi-layer deep neural networks.

In some embodiments, the optical computing operations can include: a Fourier transform operation; a convolution operation; a matrix-multiplication operation; and an arbitrary algebraic operation.

In some embodiments, the system can be programmed to perform various operations, including: feature recognition operations; associative memory operations; correlation operations; and neural network processing operations.

The disclosed embodiments also relate to a universal optical waveform transformer, which includes a metaphonic mode multiplexer that facilitates arbitrary beamforming, and a metaphonic mode demultiplexer, which facilitates arbitrary decomposition. It also includes a unitary photonic matrix element, coupled between the metaphonic mode multiplexer and the metaphonic mode demultiplexer, which facilitates converting any input spatial mode to any output spatial mode.

In some embodiments, the metaphonic mode multiplexer comprises an orbital angular momentum (OAM) state multiplexer, and the metaphonic mode demultiplexer comprises an OAM state demultiplexer.

In some embodiments, the OAM state multiplexer and the OAM state demultiplexer each comprise: a circular arrangement of apertures; a set of phase-matched waveguides coupled to the circular arrangement of apertures; and a star coupler coupled to the set of phase-matched waveguides.

In some embodiments, the unitary photonic matrix element comprises a photonic mesh that connects a set of input waveguides to a set of output waveguides. This photonic mesh incorporates 2×2 Mach-Zehnder interferometer blocks that facilitate a matrix multiplication of the complex values (the amplitude and phase of the optical fields) in the set of input waveguides to produce a result encoded in corresponding complex values on the set of output waveguides.

### BRIEF DESCRIPTION OF THE FIGURES

FIG. 1A illustrates a model of a nonlinear neuron, which includes synapses, weighted addition and a nonlinear activation function in accordance with disclosed embodiments.

FIG. 1B presents a graph illustrating nonlinear activation functions with different slope parameters in accordance with disclosed embodiments.

FIG. 2A presents a schematic diagram for a nanophotonic neuron in accordance with disclosed embodiments.

FIG. 2B illustrates a corresponding physical layout for the nanophotonic neuron illustrated in FIG. 2A in accordance with disclosed embodiments.

FIG. 3A presents a high-level diagram of a nanophotonic neural computing system in accordance with the disclosed embodiments.

FIG. 3B illustrates a readout circuit including a three-layer nanophotonic neural network in accordance with disclosed embodiments.

FIG. 3C presents a schematic diagram of a self-optimizing nanophotonic synaptic interconnect in accordance with disclosed embodiments.

FIG. 4A illustrates a unitary N×N synaptic interconnection in accordance with disclosed embodiments of an NSID.

FIG. 4B presents a photograph of a corresponding N×N WDM coupler as an NSID, which comprises a specific chip implementation of a 512×512 AWGR, in accordance with disclosed embodiments.

FIG. 4C illustrates a wavelength-specific weight table for a 6×6 synaptic interconnection in accordance with disclosed embodiments.

FIG. 4D illustrates a nanophotonic neural cluster in accordance with disclosed embodiments.

FIG. 4E illustrates an NSID with phase modulators in accordance with disclosed embodiments.

FIG. 5A illustrates an adaptive photonic array composed of metastructures in accordance with disclosed embodiments.

FIG. 5B illustrates a stack of metalenses in accordance with disclosed embodiments.

FIG. 6A illustrates electric fields associated with OAM beams in accordance with disclosed embodiments.

FIG. 6B illustrates how a beam encoded with OAM state is sampled and demultiplexed in accordance with disclosed embodiments.

FIG. 6C illustrates a fabricated silicon photonic OAM device for five spatial modes in accordance with disclosed embodiments.

FIG. 7A illustrates a 2D spatial mode multiplexer/demultiplexer created by stacking multi-layer OAM multiplexer/demultiplexer devices in accordance with disclosed embodiments.

FIG. 7B presents a photograph of a fabricated three-layer OAM multiplexer/demultiplexer device in accordance with disclosed embodiments.

FIG. 8A illustrates a universal waveform shaper and a universal decomposer in accordance with disclosed embodiments.

FIG. 8B illustrates a universal waveform composer in accordance with disclosed embodiments.

### DETAILED DESCRIPTION

The following description is presented to enable any person skilled in the art to make and use the present embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present embodiments. Thus, the present embodiments are not limited to the embodiments shown, but are to be accorded the widest scope consistent with the principles and features disclosed herein.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium. Furthermore, the methods and processes described below can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

### Discussion

The disclosed embodiments provide a system comprising energy-efficient bio-inspired nanophotonic neurons together with synapses and neural networks to interconnect them. Biological neurons are known to emit electrical pulses, or a series of stereotyped action potentials, or spikes, after receiving stimuli. Coding of information in the form of the timing of the spikes (temporal coding) and the spike rate (rate coding) has been a subject of active research. In designing nanophotonic spiking neural networks, three fundamental elements, namely the neuron, the synapses, and the coding scheme, should preferably be designed together to have: (1) weighted addition—the ability to sum weighted inputs; (2) integration—the ability to integrate the weighted sum over time; (3) thresholding—the ability to make a decision whether or not to send a spike (all-or-none); (4) reset—the ability to have a refractory period during which no firing can occur immediately after a spike is released; and (5) pulse generation—the ability to generate new pulses.

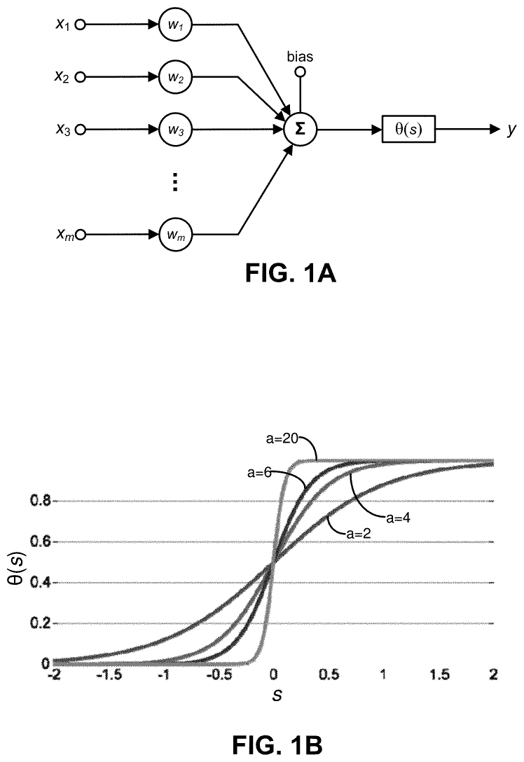

FIG. 1A illustrates a simple exemplary neuron, where the input into the neuron is a linear combination (weighted addition) of the output of other neurons. This neuron integrates the weighted signals over time and produces a nonlinear response, which is represented by an activation function. FIG. 1B illustrates this type of nonlinear activation function (e.g., sigmoid function) for different slope parameters a. The neuron's output is then broadcast to successive nodes in the network. Note that the inter-neuron connections can be weighted with positive and negative values represented as excitatory and inhibitory synapses, respectively. The synaptic interconnection network of neurons can be represented as a matrix of the weight values (wᵢⱼ) or real numbers. Moreover, the coding scheme will map the real-valued weights and represent them as spiking signals.

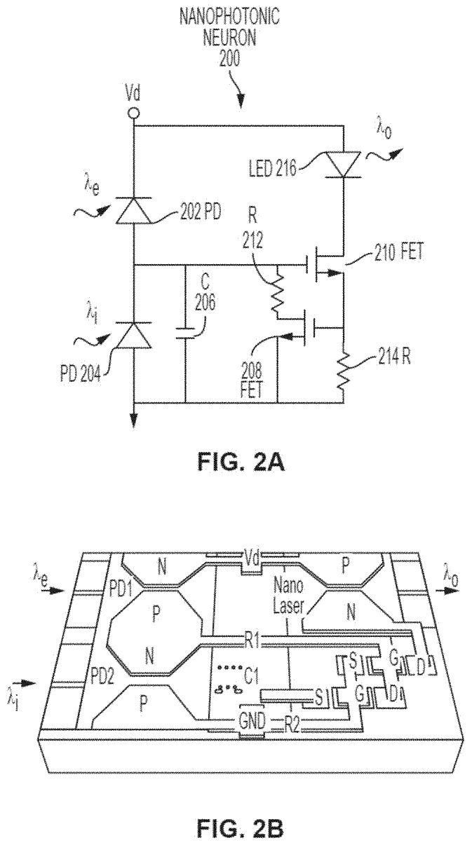

FIG. 2A presents an exemplary schematic diagram for a nanophotonic neuron 200 with a spiking electronic circuit. (See U.S. patent application Ser. No. 16/115,353, entitled “Implementing a neuromorphic computing system using nanophotonic neurons,” by inventors S. J. B. Yoo and D. A. B. Miller, filed on 28 Aug. 2018, which is hereby incorporated by reference.) As illustrated in FIG. 2A, nanophotonic neuron 200 includes: excitatory nanophotonic photodetector (PD) 202, inhibitory nanophotonic PD 204 and a nanophotonic LED 216. Other circuit elements, such as resistors 212 and 214 and capacitance C 206 (which is inclusive of the capacitances of PDs 202 and 204 and FETs 208 and 210), can be tuned to achieve a desired sigmoid response function, including temporal and rate coding.

In the nanophotonic neurons shown in FIG. 2A, the spiking electronic circuit is placed in between the nanophotonic detectors (PD 202 and PD 204) and the nanophotonic LED 216 with extremely low capacitance values C 206 to achieve ˜10 fJ/b energy efficiency with fan out. The exemplary nanophotonic neuron follows a leaky integrate-and-fire (LIF) neuron model, which exploits high quantum-efficiency PDs and LEDs with low capacitance in the ˜1 fF range. The output of PDs 202 and 204 controls the gate voltage of field-effect transistor (FET) 210, which turns on/off the LED 216 based on the strength of two input signals received through PD 202 and PD 204. The second FET 208, which is coupled with resistor 212 and capacitor C 206, serves as the feedback unit for the spiking current generation. When the input signal turns on FET 210, a spiking optical signal is generated by LED 216. When FET 210 is turned on, it also causes FET 208 to turn on, which leads to capacitor 206 being discharged, hence turning off FET 210 and completing the spiking action. Note that by replacing the input/output interfaces with nanophotonic PDs and LEDs, the neuron power consumption can be drastically reduced due to the absence of capacitive charge associated with the interconnect wires. Moreover, because of the design of the nanophotonic and FET structures, the static power consumption is extremely low. This leads to an expected static power consumption of ˜2 nW for a ˜2V supply and a reserve leakage current of ˜1 nA.

FIG. 2B illustrates a corresponding physical layout for the nanophotonic neuron illustrated in FIG. 2A in accordance with disclosed embodiments. This nanophotonic neuron can make use of a low-Q nanophotonic crystal PD based on Ge/Si cavity. Also, an ultralow capacitance nano-cavity PD can be used to generate a sufficiently large voltage without an amplifier when combined with a high impedance load. Based on this configuration, a ˜1 fF capacitance is expected in the resonant nanophotonic PD. In addition to the ultra-compact size and extremely low capacitance, the extremely short electrical contact between PDs and next stage FET transistors can provide extremely low circuit power consumption. We anticipate that such a system can operate beyond 10 GHz bandwidth with ultralow energy consumption of ˜1 fJ/bit. We can fabricate these devices on a silicon platform in which the FET, Ge/Si nanodetectors, and waveguides will be on silicon on silicon-oxide waveguides while nanolasers can utilize hybrid InAs/AlGaAs quantum-dot on silicon/SiO₂ structures with photonic crystal patterns etched in on silicon.

### Spiking Nanophotonic Neural Reservoir Computing

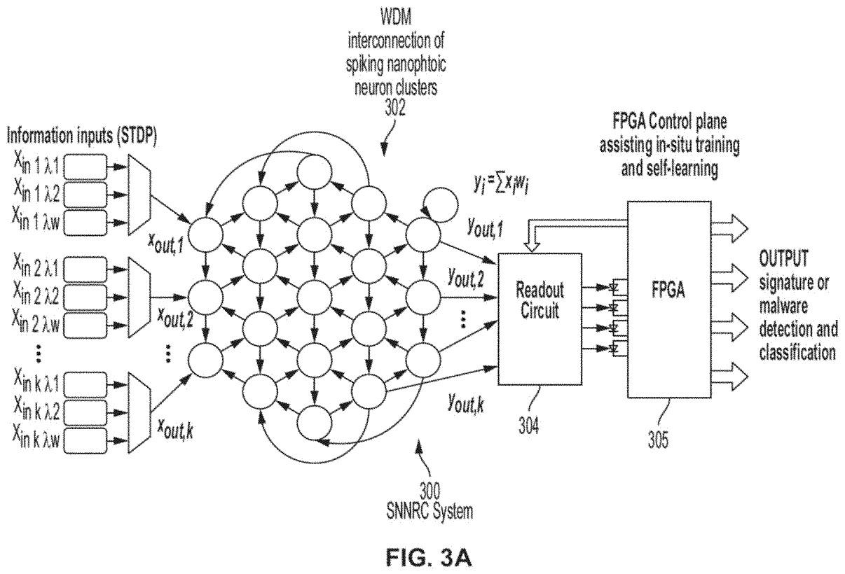

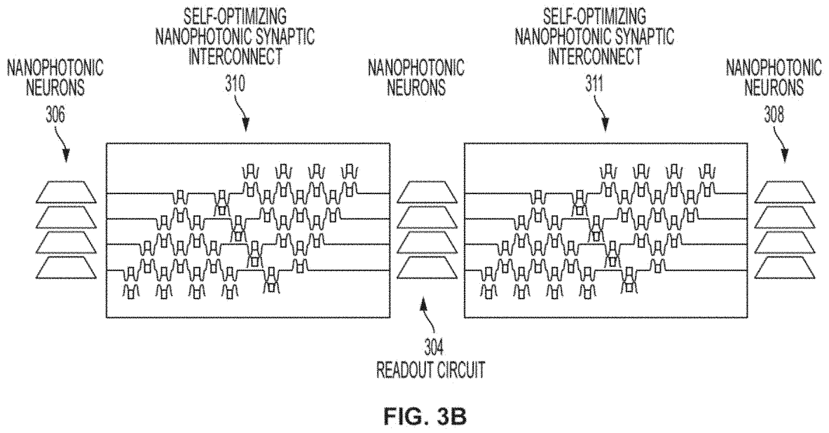

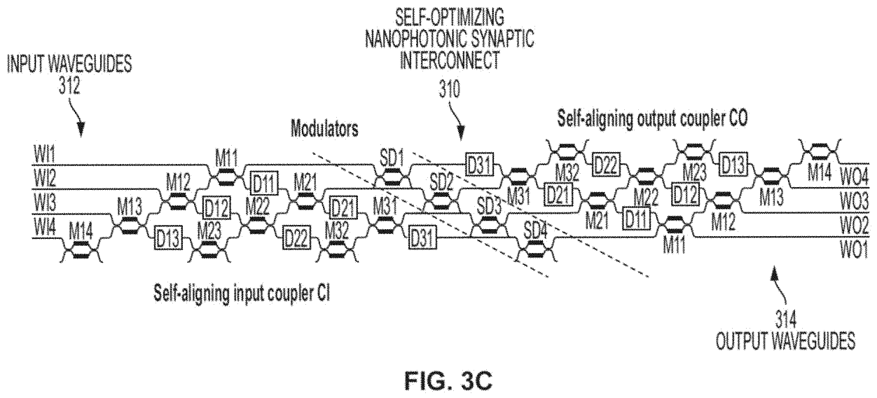

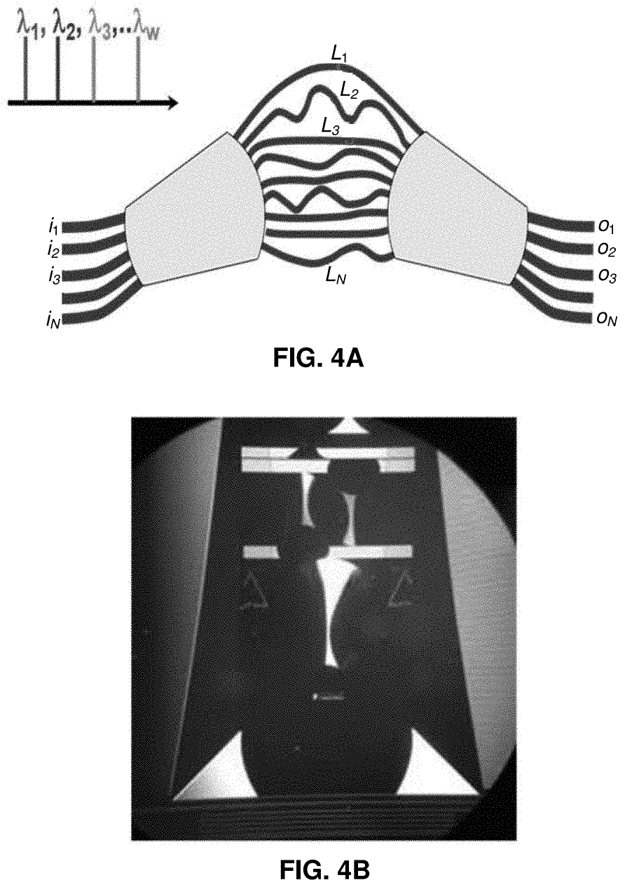

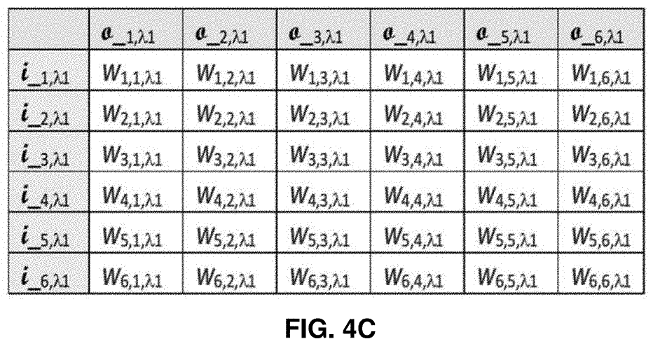

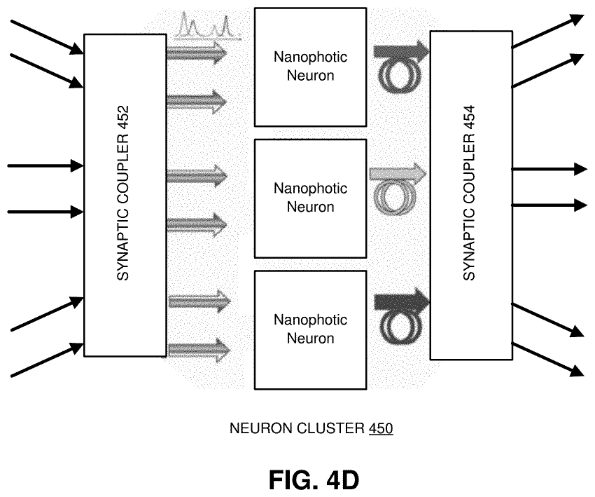

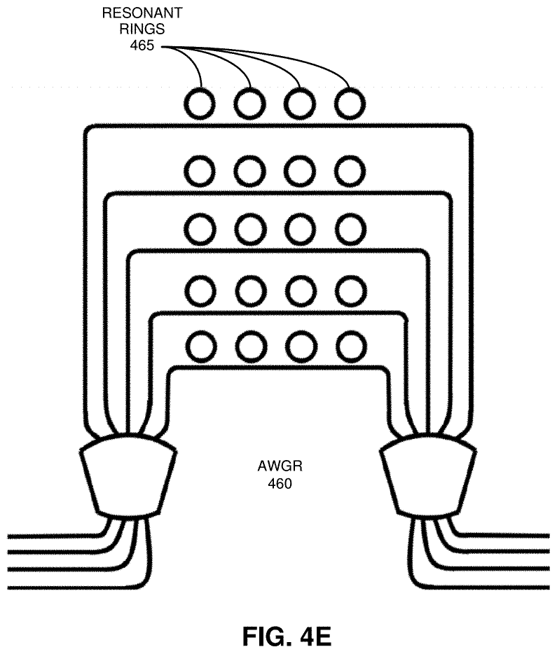

The disclosed embodiments provide an energy-efficient, high-throughput, hardware-reduced, scalable, robust, and accurate machine learning system based on a spiking nanophotonic neural reservoir computing (SNNRC) system 300, which is conceptually illustrated in FIG. 3A. This SNNRC system 300 includes a wavelength division multiplexed (WDM) interconnection of spiking nanophotonic neuron clusters 302. Referring to FIG. 4D, each neuron cluster 450 contains an array of spiking nanophotonic neurons placed between synaptic coupler 452 and synaptic coupler 454 that provide fixed synaptic weights at each wavelength of the WDM SNNRC system 300. Arbitrary WDM interconnections between the nanophotonic neuron cluster nodes can provide a recursive neural network (RNN) in the photonic reservoir. A readout circuit 304 channels outputs to detectors on FPGA 305.

As illustrated in more detail in FIG. 3B, readout circuit 304 includes a multilayer (e.g., three) nanophotonic neural network comprising arrays of nanophotonic neurons 306-308 connected by self-optimizing nanophotonic synaptic interconnect networks 310-311 comprised of reconfigurable 2×2 couplers. During operation, readout circuit 304 can work with the embedded detectors in the nanophotonic neural network to self-configure and in-situ train read-out circuit 304 through a feed-forward process, possibly combined with a back-propagation technique modified for a spiking timing dependent plasticity (STDP) system. During operation of SNNRC system 300, input data (possibly containing malware) can be STDP-coded on WDM spikes, wherein the system processes these WDM spikes to perform signature detection and malware detection on a large amount of data at high speed and with good energy efficiency.

The self-optimizing nanophotonic synaptic interconnect 310 illustrated in FIG. 3C provides weighted connections from a set of optical inputs that are directed into a set of input waveguides 312 to a set of optical outputs that are produced by a set of output waveguides 314. (See U.S. patent application Ser. No. 16/115,353 cited above. Also see S. Pai, B. Bartlett, O. Solgaard, and D. A. B. Miller, “Matrix Optimization on Universal Unitary Photonic Devices,” Phys. Rev. Appl., vol. 11, no. 6, p. 064044, June 2019, doi: 10.1103/PhysRevApplied.11.064044.)

Referring to FIG. 3C, an exemplary self-optimizing nanophotonic synaptic interconnect 310 can be implemented using a network of 2×2 NEMS-MZI synapses (here the elements M11, M12, etc.) connected in a mesh. Note that this interconnect can implement any linear transform from its inputs (which would be the outputs of the neurons) to its outputs (which would be the inputs to the next layer of neurons).

Unlike previous optical interconnects, this can be accomplished without having to throw away any of the optical power unless necessary for the desired linear mapping. There also exist a number of simple techniques for configuring such networks, which have been successfully demonstrated in such meshes. In particular, such networks can be configured by a simple training operation that maps arbitrary inputs to specific outputs. This training requires no calculations or calibrations to set the mesh components, and the mesh can even realign to compensate for any drifts in components or to new training vectors. These techniques work by using a succession of simple feedback loops on Mach-Zehnder settings, which are based on power minimization in the embedded detectors D11-D31 illustrated in FIG. 3C.

Alternatively, the 2×2 MZI synapses can be implemented by incorporating phase-change materials instead of MEMS or NEMS. For example, see “Low-Loss and Broadband Nonvolatile Phase-Change Directional Coupler Switches,” Peipeng Xu, Jiajiu Zheng, Jonathan K. Doylend and Arka Majumdar, ACS Photonics 2019, 6, 2, 553-557, Jan. 7, 2019. This article demonstrates how GeSbTe (GST) or Ge₂Sb₂Se₄Teₜ(GSST) materials embedded in an MZI can be used to implement a nonvolatile 2×2 synapse.

### Multi-Wavelength Neuron Clusters and Synaptic Interconnections

We now discuss how a single-wavelength spiking neural network can be extended to a WDM spiking neural reservoir computing network with far greater interconnectivity. If each spiking neuron emits at its own characteristic wavelength and receives spikes at multiple wavelengths, then significant enhancement of interconnectivity is possible (by a factor of w, where w is the number of wavelength channels). For example, in the context of the system 300 illustrated in FIG. 3A for a single wavelength, each circle represents one nanophotonic neuron receiving spikes from K neighboring neurons and emitting one wavelength spike to K other neighboring neurons. In contrast, when utilizing WDM, each circle in FIG. 3A can represent a cluster of W nanophotonic neurons emitting W individual wavelength spikes interconnecting with K other neighboring neurons each containing W other nanophotonic neurons. Hence, KW×KW synaptic interconnections can be achieved utilizing WDM couplers. Unlike electronic or previous optical neural networks, we can implement unitary and lossless interconnections by using the N×N WDM coupler between one layer of nanophotonic neurons to the next layer of nanophotonic neurons as is illustrated in FIG. 4A. Assuming K=W=N, each input port i₁, i₂, . . . i_{N} carries N wavelength spikes from N neurons from N clusters (total of N²), and splits each spike to N output ports o₁, o₂, . . . o_{N}. Note that the weight of the interconnection between the iᵢ and oⱼ at wavelength λl denoted w_{i,j,λl} depends on the choices of the optical array arm lengths L_{I}, L₂, . . . L_{M}. For reservoir computing, this w_{i,j,λl} value can be considered as synaptic weight (of fixed value although reconfigurable or tunable) between the neurons. For example, FIG. 4C presents a 6×6 synaptic interconnection weight table at λ₁; note that similar tables of different weight values exist for λ₂, λ₃, λ₄, λ₅, and λ₆.

FIG. 4B shows a photograph of such a WDM coupler for 512×512 (N=K=W=512) arrayed-wave-guide-grating-router (AWGR) capable of supporting 512²×512² interconnection of neurons. (See S. Cheung, S. Tiehui, K. Okamoto, and S. J. B. Yoo, “Ultra-Compact Silicon Photonic 512×512 25 GHz Arrayed Waveguide Grating Router,” Selected Topics in Quantum Electronics, IEEE Journal of, vol. 20, pp. 310-316, 2014.) This example, which is implemented on a silicon photonic platform, uses linearly increasing optical array arms (Lₚ=L₀+p*ΔL, where L₀ and ΔL are constants) to achieve wavelength routing among 512 ports. However, the arbitrary lengths of the optical array arms can provide diverse w_{i,j,λl} design values as lossless synaptic interconnects that are relatively insensitive to temperature compared to WDM interconnects using micro resonator rings. (See A. N. Tait, T. F. de Lima, M. A. Nahmias, B. J. Shastri, and P. R. Prucnal, “Multi-channel control for microring weight banks,” Optics Express, vol. 24, pp. 8895-8906, 2016.)

Because the N×N WDM coupler illustrated in FIG. 4A achieves only a linear interconnection, we can design a cluster of N nanophotonic neurons including N inhibitory and excitatory PDs with a 2N×2N WDM coupler at the input and an N×2N WDM coupler at the output. Note that a biologically analogous implementation of a neural network may include separate excitatory neurons and inhibitory neurons with a 4:1 ratio in separate clusters. However, it is possible to include both in each cluster by appropriately assigning the weight values w_{i,j,λl} and using a nonunitary N×2N WDM coupler to support excitatory and inhibitory outputs. Because these WDM couplers provide synaptic interconnections, we will name them synaptic coupler 452 and synaptic coupler 454, respectively, as is illustrated in FIG. 4D. Although the illustration in FIG. 4D is for N=K=W=3, a much higher N of ˜512 can be implemented.

The N×N WDM coupler illustrated in FIG. 4A is implemented in an arrayed waveguide grating router (AWGR) that has been modified to include phase modulators in the form of resonant rings 465, which are used to set specific interconnection weights as is illustrated in FIG. 4E. These resonant rings 465 are over-coupled to corresponding waveguides so that optical loss is nearly negligible regardless of the wavelength setting. Note that each ring in the AWGR can be thermally or electro-optically tuned to have the resonant wavelength be on the blue or red side of the laser wavelength (λ₁, λ₂, λ₃, λ₄) so that the optical phase can be modulated from zero to 2π.

This type of modulation can be implemented using a ring-assisted Mach-Zehnder modulator, as is described in “Differential Microring Modulators for Intensity and Phase Modulation: Theory and Experiments,” Chia-Ming Chang, Guilhem de Valicourt, S. Chandrasekhar and Po Dong, Journal of Lightwave Technology, vol. 35, issue 15, August 2017. These resonators can be wavelength-tuned using thermal, electro-optical and mechanical-optical mechanisms, and also by incorporating phase-change materials into the resonators.

Phase-change-materials, such as GST, can be used in a Fabry-Perot filter to selectively transmit or block the part of the spectrum of interest. By forming an aperture and placing the GST layer in between the top and the bottom distributed Bragg reflectors (DBRs), one can create a phase-change-tunable-filter. Application of long (short) electrical pulses to the GST layer will change the phase of the GST layer from amorphous to crystalline (crystalline to amorphous), which will change the optical refractive index from 6.2 to 3.5 (3.5 to 6.2) while the material loss is relatively low. See S. J. Ben Yoo, “Nanophotonic computing: scalable and energy-efficient computing with attojoule nanophotonics,” in 2017 IEEE Photonics Society Summer Topical Meeting Series (SUM), 2017, pp. 1-2. Also, see J. Hu, K. Zhang, and S. J. Ben Yoo, “Hardware-Based Simulation of Optoelectronic Spiking Neuromorphic Computing Network,” in Conference on Lasers and Electro-Optics, 2019, p. JTh2A.68.

For a description of how phase change materials in optical resonators can be more readily integrated with planar waveguides, such as AWGRs, see “All-optical non-volatile tuning of an AMZI-coupled ring resonator with GST phase-change material,” Hanyu Zhang, Linjie Zhou, Jian Xu, Liangjun Lu, Jianping Chen, and B. M. A. Rahman, Optics Letters, vol. 43, Issue 22, pp. 5539-5542, 2018. Also see “Optical switching at 1.55 μm in silicon racetrack resonators using phase change materials,” Miquel Rudé, Josselin Pello, Johann Osmond, Gunther Roelkens, Jos J. G. M. van der Tol, and Valerio Pruneri, Appl. Phys. Lett. 103, 141119, 2013.

Nanophotonic Computing System that Uses Metalenses

Recent developments in metaphotonics and integrated photonic technologies have resulted in flat optical lenses that can be integrated on LCDs and detectors in vertical stacks, suggesting a path toward scalable multi-layer convolutional neural networks. Also, very complex artificial neural networks (ANN) that support reinforcement learning and unsupervised learning have been developed. Hence, it is now possible to envision new computing systems comprising metaphotonic and optoelectronic components with 2D and 3D integration.

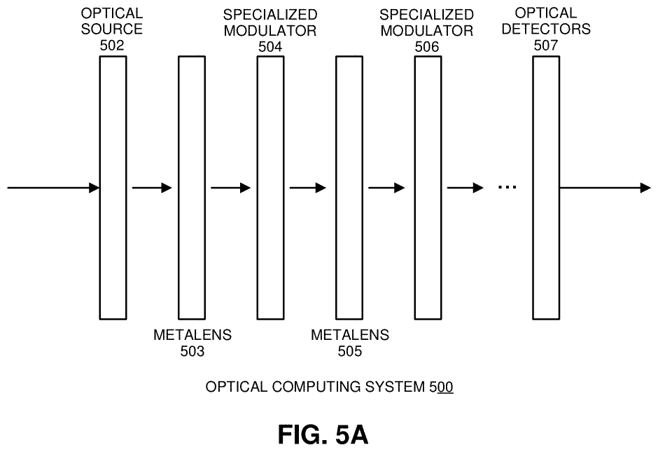

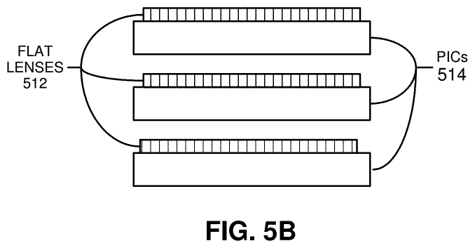

Referring to FIG. 5A, this type of optical computing system 500 may comprise: an optical source 502; a stack of metalenses 503 and 505 with intervening specialized modulators 504 and 506; and optical detectors 507. The metalenses 503 and 505 illustrated in FIG. 5A can be implemented as “flat lenses” comprising a metastructure of subwavelength scale elements that can achieve extremely high quality lensing with high numerical apertures with a capability to be integrated on LCDs, LEDs, detector arrays or other 2D and 3D photonic integrated circuits. (For further details about metalenses 503 and 505, please see M. Khorasaninejad and F. Capasso, “Metalenses: Versatile multifunctional photonic components,” Science, vol. 358, 2017, and M. Khorasaninejad, W. T. Chen, R. C. Devlin, J. Oh, A. Y. Zhu, and F. Capasso, “Metalenses at visible wavelengths: Diffraction-limited focusing and subwavelength resolution imaging,” Science, vol. 352, pp. 1190-1194, 2016.) Specialized modulators 504 and 506 can be implemented using liquid-crystal on silicon (LCOS) spatial light modulators. (See Zhang, Z., You, Z. & Chu, D. Fundamentals of phase-only liquid crystal on silicon (LCOS) devices. Light Sci Appl 3, e213, 2014.) For example, a silicon substrate with liquid crystal on it can be used to implement an LCOS-based specialized modulator, which can be programmed by using an electrical field to change characteristics of the liquid crystal. This effectively provides electro-optical modulation.

For example, FIG. 5B illustrates an implementation comprising a vertical stack of flat lenses 512 with 2D photonic integrated circuits (PICs) 514 in between each layer. (See M. Khorasaninejad, W. T. Chen, R. C. Devlin, J. Oh, A. Y. Zhu, and F. Capasso, “Metalenses at visible wavelengths: Diffraction-limited focusing and subwavelength resolution imaging,” Science (80-.)., vol. 352, no. 6290, pp. 1190 LP-1194, June 2016, doi: 10.1 126/science.aaf6644. Also see M. Khorasaninejad, Z. Shi, A. Y. Zhu, W. T. Chen, V. Sanjeev, A. Zaidi, and F. Capasso, “Achromatic Metalens over 60 nm Bandwidth in the Visible and Metalens with Reverse Chromatic Dispersion,” Nano Lett., 2017, doi: 10.1021/acs.nanolett.6b05137. Also see J.-S. Park, S. Zhang, A. She, W. T. Chen, P. Lin, K. M. A. Yousef, J.-X. Cheng, and F. Capasso, “All-Glass, Large Metalens at Visible Wavelength Using Deep-Ultraviolet Projection Lithography,” Nano Lett., vol. 19, no. 12, pp. 8673-8682, December 2019, doi: 10.1021/acs.nanolett.9b03333.)

In the system illustrated in FIG. 5B, note that the 2D PICs can be LCDs, LEDs, or detector arrays to achieve a miniaturized implementation for optical convolution, optical FFTs, optical pattern recognitions, and optical associative memory, which are very important in modern “deep” neural networks. Considering that more than 90% of energy consumption for typical convolutional neural network (CNN) workloads is involved in performing the convolution operation itself, harnessing a photonic neural network utilizing metalenses and 2D/3D photonic-electronic integrated circuits can greatly reduce complexity and the energy consumption for neural network operations. This paves a path toward scalable, multi-layer convolutional neural networks for extremely high throughput processing on low power platforms, such as handheld devices.

### Nanophotonic Mode Multiplexers and Demultiplexers

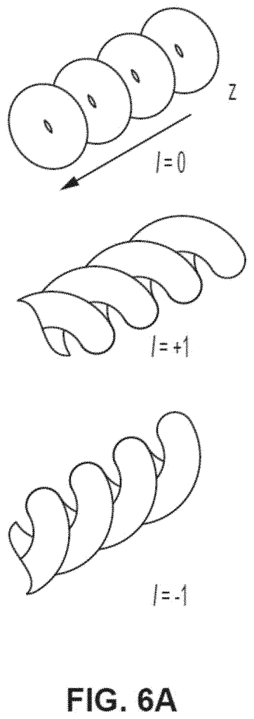

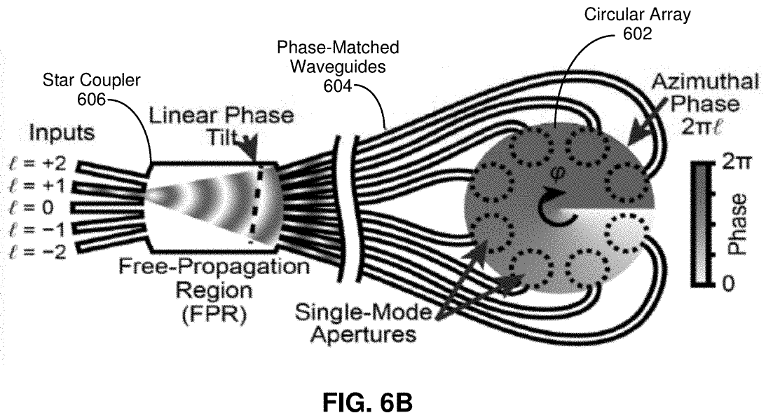

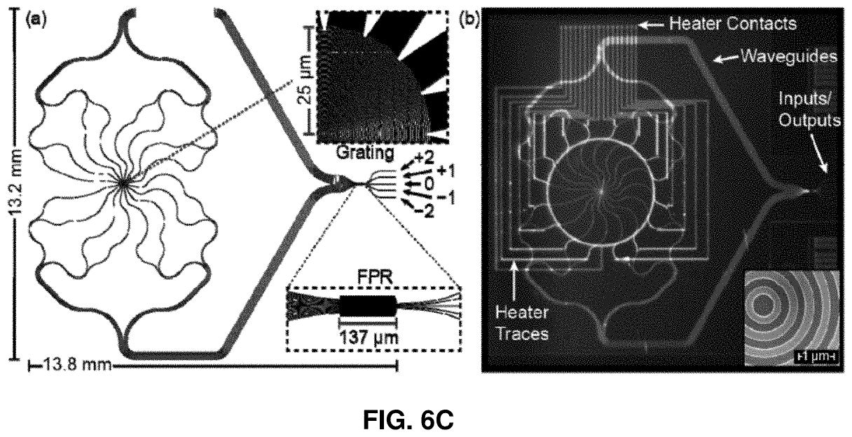

In order to decompose and process optical information and to reconstruct optical information, we investigated all optical spatial multiplexers and demultiplexers utilizing silicon photonics. Our initial demonstration utilized orbital angular momentum (OAM) state multiplexing and demultiplexing. (See L. Allen, M. W. Beijersbergen, R. J. C. Spreeuw, and J. P. Woerdman, “Orbital angular momentum of light and the transformation of Laguerre-Gaussian laser modes,” Physical Review A, vol. 45, pp. 8185-8189, 1992.) FIG. 6A shows examples of a light beam with different OAM states that have an azimuthal (i.e., in the transverse plane) phase variation of φ(r,φ)=exp(ilφ), where i²=1, φ is the azimuthal (angular) coordinate and l can be any positive or negative integer value (known as the topological charge). This type of beam has helical phase fronts, where the handedness (direction of twist) depends on the sign of l and the number of intertwined helices depends on the magnitude of l (i.e., the number of 2π phase shifts that occur in one revolution of the azimuthal angle φ). FIG. 6B illustrates an OAM multiplexer/demultiplexer, wherein a circular array 602 of waveguide grating couplers is used to sample areas (dashed circles) of an incoming beam encoded with an OAM state (e.g., l=1) into a corresponding array of single-mode, phase-matched waveguides 604 and a star coupler 606. FIG. 6C presents a photograph of an OAM multiplexer/demultiplexer fabricated on a silicon-on-insulator (SOI) material platform, which provides a multiplexer/demultiplexer of OAM states (labeled as l=+2, +1, 0, −1, −2).

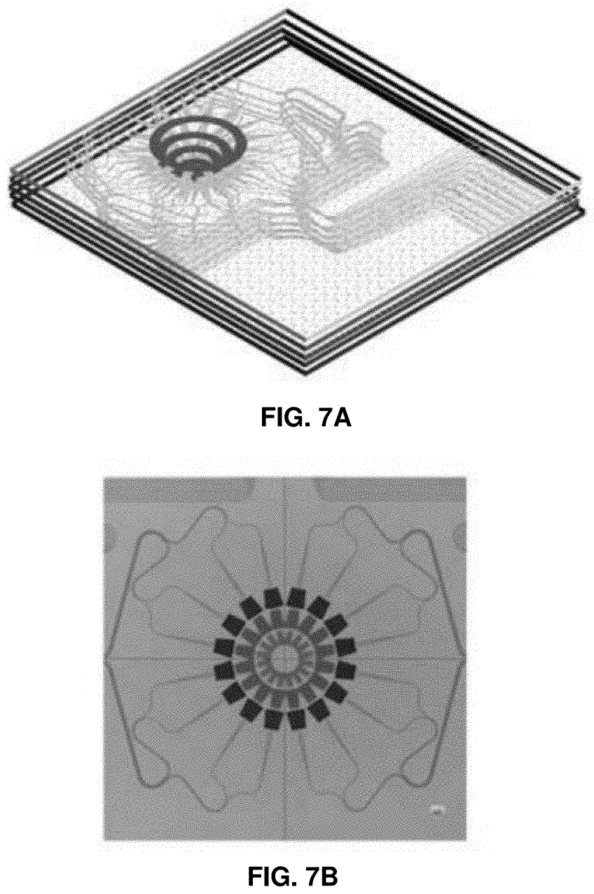

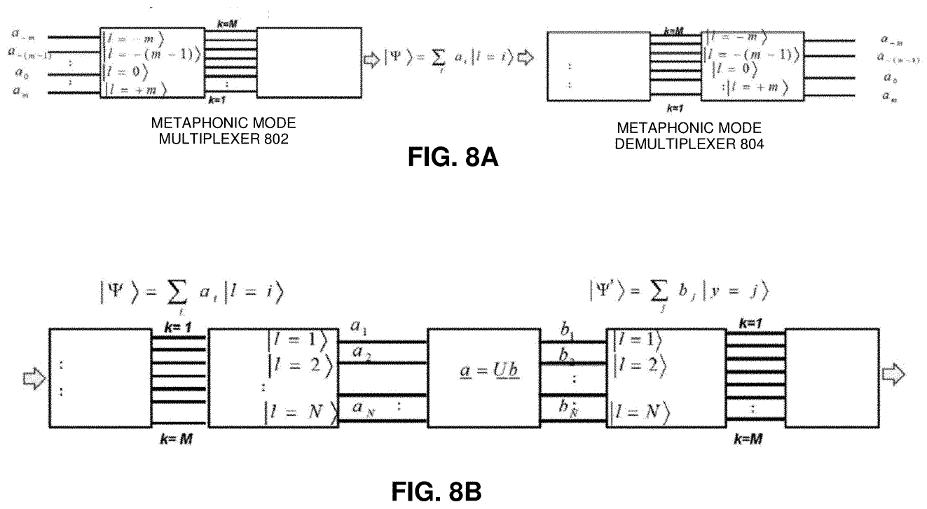

It is presently possible to create a 2D spatial mode multiplexer/demultiplexer utilizing multiples of the OAM mode multiplexer/demultiplexer at multiple radii. FIG. 7A illustrates this concept, wherein a 2D spatial mode multiplexer/demultiplexer is created by stacking multi-layer OAM multiplexer/demultiplexer devices. FIG. 7B presents a photograph of a fabricated 3-layer OAM multiplexer/demultiplexer device. Utilizing metaphotonics instead of the multilayer gratings, it is possible to implement efficient metaphotonic mode multiplexers and demultiplexers for optical beams of arbitrary spatial modes. Utilizing the demultiplexer device concept illustrated in FIG. 7A, an arbitrary optical beam input can be decomposed into multiples of the LG eigenmodes. Conversely, an arbitrary optical beam output can be constructed by providing multiple inputs to the multiplexer device of FIG. 7A by superposition of multiple LG eigenmodes at different weights. The metaphonic mode multiplexer 802 in FIG. 8A provides such a superposition, and metaphonic mode demultiplexer 804 provides a corresponding decomposition.

As discussed above and as is illustrated in FIG. 8A, a metaphotonic mode multiplexer 802 allows arbitrary beamforming, and metaphotonic mode demultiplexer 804 allows arbitrary beam decomposition of eigenvectors. Then, as illustrated in FIG. 8B, placing the two modules from FIG. 8A with a unitary matrix element “U” between them realizes a universal spatial waveform transformer that can convert any input spatial mode to any output spatial mode. This waveform transformation can also provide an arbitrary linear computation function in the optical domain.

Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the principles and features disclosed herein.

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

1. A nanophotonic computing system, comprising:
a set of nanophotonic computing elements; and
an optical interconnect, which interconnects the set of nanophotonic computing elements;
wherein the optical interconnect includes at least one reconfigurable nanophotonic synaptic interconnect device (NSID) comprising tunable phase modulators in arrayed waveguides and free-propagation regions.

2. The nanophotonic computing system of claim 1, wherein the NSID is an arrayed-waveguide grating router (AWGR), which provides cyclic, single-wavelength, all-to-all routing between AWGR inputs and AWGR outputs;
wherein the AWGR comprises free-space propagation regions connected by an array of waveguides to facilitate routing different wavelengths; and
wherein waveguides in the array of waveguides include phase modulators for varying optical lengths of the waveguides, wherein varying the optical lengths of the waveguides facilitates adjusting weights on interconnections through the AWGR in a lossless manner.

3. The nanophotonic computing system of claim 1, wherein the set of nanophotonic computing elements comprises a set of spiking nanophotonic neurons, wherein each spiking nanophotonic neuron operates by integrating weighted outputs received from other spiking nanophotonic neurons, and producing a threshold-based nonlinear response that generates output pulses, which are broadcast to other spiking nanophotonic neurons.

4. The nanophotonic computing system of claim 2,
wherein the set of spiking nanophotonic neurons is interconnected through the NSID to form a recurrent neural network; and
wherein synaptic weights in the recurrent neural network can be adjusted by using the phase modulators in the NSID to adjust corresponding interconnection weights in the NSID.

5. The nanophotonic computing system of claim 4, wherein the synaptic weights can be positive weights or negative weights.

6. The nanophotonic computing system of claim 4, wherein the nanophotonic computing system is organized as a set of interconnected neuron clusters, wherein each neuron cluster comprises:
an array of spiking nanophotonic neurons;
an input synaptic coupler comprising an input NSID connecting inputs of the neuron cluster to inputs of the array of spiking nanophotonic neurons; and
an output synaptic coupler comprising an output NSID connecting outputs of the array of spiking nanophotonic neurons to outputs of the neuron cluster.

7. The nanophotonic computing system of claim 6, wherein the nanophotonic computing system additionally comprises:
a readout circuit comprising a nanophotonic neural network with reconfigurable couplers and an array of spiking nanophotonic neurons; and
a set of detectors, which work with embedded detectors in the recurrent neural network to self-configure and in-situ train the readout circuit through a feed-forward process.

8. The nanophotonic computing system of claim 7, wherein the reconfigurable couplers comprise 2×2 Nano-Electro-Mechanical System (NEMS)-Mach-Zehnder interferometer (MZI) synapses.

9. The nanophotonic computing system of claim 8, wherein the NEMS-MZI synapses include tunable NEMS phase shifters.

10. The nanophotonic computing system of claim 7, wherein the reconfigurable couplers comprise 2×2 synapses composed of a phase-change material embedded in an MZI.

11. The nanophotonic computing system of claim 10, wherein the phase-change material comprises GeSbTe (GST) or Ge₂Sb₂Se₄Te₁ (GSST).

12. The nanophotonic computing system of claim 1, wherein the phase modulators in the NSID comprise thermo-optic phase modulators or electro-optic phase modulators.

13. The nanophotonic computing system of claim 11, wherein the phase modulators in the NSID comprise resonant rings, which are over-coupled to corresponding waveguides in the NSID so that optical loss is nearly negligible regardless of wavelength, wherein the resonant rings can be thermally or electro-optically tuned to have resonant wavelengths on the blue or red side of a corresponding laser wavelength so that the optical phase can be modulated from zero to 2π.

14. The nanophotonic computing system of claim 2, wherein each nanophotonic neuron in the set of spiking nanophotonic neurons comprises:
an excitatory-input photo detector that converts an optical excitatory input signal into a corresponding electrical excitatory input signal;
an inhibitory-input photo detector that converts an optical inhibitory input signal into a corresponding electrical inhibitory input signal;
an electrical neuron that receives the electrical excitatory and inhibitory input signals, and generates an electrical output signal, which includes periodic voltage spikes that are triggered by integration of the electrical excitatory and inhibitory input signals; and
a light-emitting output device, which converts the electrical output signal into a corresponding optical output signal.

15. The nanophotonic computing system of claim 14, wherein the electrical neuron implements an integrate-and-fire model, wherein the electrical excitatory and inhibitory input signals are integrated until a firing threshold is reached, which causes the electrical neuron to fire and generate a voltage spike on the electrical output signal.

16. A nanophotonic computing system, comprising:
an optical source;
a stack of photonic layers composed of metalenses and intervening specialized modulators, wherein each metalens comprises a flat lens metastructure composed of subwavelength scale elements, and wherein each specialized modulator comprises a modulator metastructure composed of subwavelength scale elements; and
an optical detector array;
wherein the nanophotonic computing system is configured to channel light emanating from the optical source through the stack of photonic layers and onto the optical detector array to facilitate optical computing operations.

17. The nanophotonic computing system of claim 16, wherein each specialized modulator comprises a liquid-crystal-on-silicon-based spatial light modulator.

18. The nanophotonic computing system of claim 16, wherein the metalenses perform wavelength-dependent diffraction, focusing and collimating operations.

19. The nanophotonic computing system of claim 16, further comprising an optical or electrical feedback path that facilitates cycling through the stack of photonic layers to perform iterative processing operations.

20. The nanophotonic computing system of claim 16, where the optical computing operations include one or more of the following:
a Fourier transform operation;
a convolution operation;
a matrix-multiplication operation; and
an arbitrary algebraic operation.

21. The nanophotonic computing system of claim 16, wherein the nanophotonic computing system can be programmed to perform various operations, including:
feature recognition operations;
associative memory operations,
correlation operations; and
neural network processing operations.

22. A universal optical waveform transformer, comprising:
a metaphonic mode multiplexer, which facilitates arbitrary beamforming;
a metaphonic mode demultiplexer, which facilitates arbitrary decomposition; and
a unitary photonic matrix element, coupled between the metaphonic mode multiplexer and the metaphonic mode demultiplexer, which facilitates converting any input spatial mode to any output spatial mode.

23. The universal optical waveform transformer of claim 22,
wherein the metaphonic mode multiplexer comprises an orbital angular momentum (OAM) state multiplexer; and
wherein the metaphonic mode demultiplexer comprises an OAM state demultiplexer.

24. The universal optical waveform transformer of claim 23, wherein the OAM state multiplexer and the OAM state demultiplexer each comprise:
a circular arrangement of apertures;
a set of phase-matched waveguides coupled to the circular arrangement of apertures; and
a star coupler coupled to the set of phase-matched waveguides.

25. The universal optical waveform transformer of claim 22,
wherein the unitary photonic matrix element comprises a photonic mesh that connects a set of input waveguides to a set of output waveguides; and
wherein the photonic mesh incorporates 2×2 Mach-Zehnder interferometer blocks that facilitate a matrix multiplication of amplitudes in the set of input waveguides to produce a result encoded in corresponding amplitudes on the set of output waveguides.

26. An orbital angular momentum (OAM) state multiplexer/demultiplexer, comprising:
a circular arrangement of apertures;
a set of phase-matched waveguides coupled to the circular arrangement of apertures; and
a star coupler coupled to the set of phase-matched waveguides.
